(19) United States
(12) Patent Application Publication
(10) Pub. No.: US 2005/0274985 A1
(43) Pub. Date: Dec. 15, 2005

(54) RF decoupled field plate for FETs

(76) Inventor: Michael G. Adlerstein, Wellesley, MA (US)

Correspondence Address: DALY, CROWLEY, MOFFORD & DURKEE, LLP, SUITE 301A, 354A TURNPIKE STREET, CANTON, MA, 02021-2714, US

(21) Appl. No.: 10/854,719

(22) Filed: May 26, 2004

(51) Int. Cl. H01L 29/76

(52) U.S. Cl. 257/213

(57) ABSTRACT

A field effect transistor structure having a field effect transistor; a field plate disposed between a gate electrode of the transistor and a drain electrode of the transistor; and a resistive interconnect electrically connected between the gate electrode and the field plate. With such an arrangement, the field plate is RF decoupled from the gate.

### TECHNICAL FIELD

This invention relates to field effect transistors (FETs), and more particularly to field plates used in such FETs.

### BACKGROUND

As is known in the art, a field plate is a metallic stripe on dielectric positioned between the gate and drain of a field effect transistor and is electrically connected to the transistor gate to alter electric field boundary conditions. The result is that the peak electric field in the conducting channel is significantly reduced. This increases the DC breakdown voltage of the transistor which is beneficial to its reliability. However, the connection results in a significant increase in the gate to source capacitance of the transistor, thereby decreasing transistor gain at microwave frequencies. The present invention suggests a method of decoupling the gate and the field plate at rf frequencies while maintaining the connection at DC to beneficially modify the electric fields.

FIGS. 1A and 1B show a cross-sectional comparison of a FET with (FIG. 1B) and without (FIG. 1A) a field plate. The electric fields are perpendicular to the contours of isopotentials shown. For a given gate-drain voltage, the Field Plate reduces the maximum DC electric field at the gate. The field plate results in a spreading of the depleted region resulting in reduced electric field near the gate as desired as shown in FIG. 1B. The result is that the peak electric field in the conducting channel is significantly reduced. This increases the DC breakdown voltage of the transistor that is beneficial to its reliability. Typically the field plate is electrically connected to each gate in the transistor cell. Thus, the capacitance of the field plate C_{fp} is electrically in parallel with the gate and the connection results in a significant increase in the gate to source capacitance of the transistor, thereby decreasing transistor gain at microwave frequencies. More particularly, the resulting increase in capacitance diminishes the frequency response of the transistor as characterized by the cutoff frequency for current gain fₜ given by Eq. 1 below:

$${f}_{t} = \frac{{g}_{m}}{2 \cdot π ( {C}_{gs} + {C}_{fp} )} \qquad Eq . 1$$

Here, gₘ is the transconductance and C_{gs} is the usual gate to source capacitance.

### SUMMARY

In accordance with the present invention, a field effect transistor structure is provided having a field effect transistor; a field plate disposed between a gate electrode of the transistor and a drain electrode of the transistor; and a resistive interconnect electrically connected between the gate electrode and the field plate.

With such an arrangement, the field plate is RF decoupled from the gate.

In accordance with another feature of the invention, a field effect transistor structure is provide having a plurality of field effect transistors; a field plate bus; and a plurality of field plates, each one being disposed between a gate electrode and a drain electrode of a corresponding one of the plurality of transistors, each one of the plurality of field plates being connected to the field plate bus.

In one embodiment, a voltage source is connected to the field plate bus.

In accordance with another feature of the invention, a field effect transistor structure is provided having: a plurality of field effect transistors; a field plate bus; a plurality of field plates, each one being disposed between a gate electrode and a drain electrode of a corresponding one of the plurality of transistors, each one of the plurality of field plates being connected to the field plate bus; and a plurality of resistive interconnects, each one being electrically connected to the gate electrode and the field plate of a corresponding one of the transistors.

In accordance with another feature of the invention, a field effect transistor structure is provided having: a plurality of field effect transistors; a field plate bus; a plurality of field plates, each one being disposed between a gate electrode and a drain electrode of a corresponding one of the plurality of transistors, each one of the plurality of field plates being connected to the field plate bus. The field plate bus comprises a resistive material electrically connected to the gate electrode and the field plate of a corresponding one of the transistors.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIGS. 1A and 1B show a cross-sectional comparison of a FET with (FIG. 1B) and without (FIG. 1A) a field plate.

FIG. 2 is a plan view sketch of a transistor structure according to the invention;

FIG. 3 is a cross sectional view of the transistor structure of FIG. 2, such cross section being taken along line 2-2 of FIG. 2;

FIG. 4 is a plan view sketch of a transistor structure according to an alternative embodiment of the invention;

FIG. 5 is a cross sectional view of the transistor structure of FIG. 4, such cross section being taken along line 4-4 of FIG. 4;

FIG. 6 is a cross sectional view of the transistor structure of FIG. 3, such cross section being taken along line 5-5 of FIG. 4; and

FIG. 7 is an equivalent circuit of a resistive field plate bus used in the transistor structure of FIG. 4.

Like reference symbols in the various drawings indicate like elements.

### DETAILED DESCRIPTION

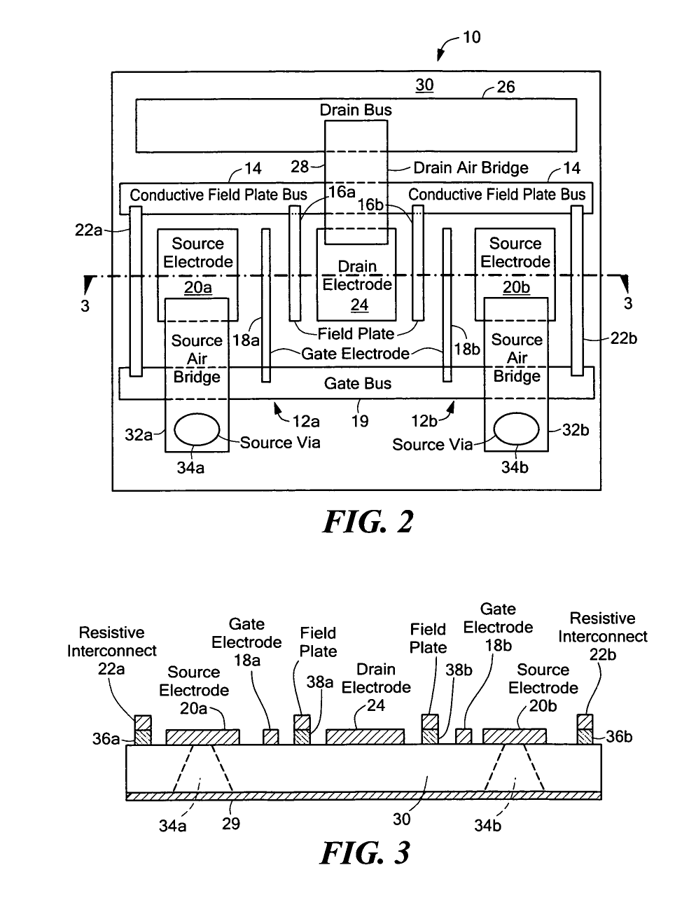

Referring now to FIGS. 2 and 3, a field effect transistor structure 10 is shown to include a plurality of, here two field effect transistors 12a, 12b, a conductive field plate bus 14; a plurality of, here a pair of, conductive field plates 16a, 16b, each one being disposed between a gate electrode 18a, 18b and a drain electrode 20a, 20b of a corresponding one of the pair of transistors 12a, 12b, respectively. Each one of the pair of field plates 16a, 16b is electrically connected to the field plate bus 14. The structure 10 also includes a pair of resistive interconnects 22a, 22b, each one being electrically connected to the gate electrode 18a, 18b of transistors 12a, 12b through a conductive gate bus 19 and to the field plates 16a, 16b of a corresponding one of the transistors 12a, 12b, respectively through the field plate bus 14. The pair of transistors 12a, 12b share a common drain electrode 24. The common drain electrode 24 is connected to a drain bus 26 through an air bridge interconnect 28, as shown. The structure 10 is disposed on common semiconductor substrate 28, such as silicon carbide. A ground plane conductor 29 is formed on the bottom of the substrate 30. The ground plane conductor 29 is electrically connected to the source electrodes 20a, 20b by source air bridge conductors 32a, 32b, respectively and conductively plated vias 34a, 34b, respectively.

The resistive interconnects 22a and 22b are insulated from the substrate 30 by a dielectric material 36a, 36b, respectively. Likewise, the conductive field plates 16a and 16b are insulated from the substrate 30 by here a dielectric material 38a, 38b, respectively. As is known, the source and drain electrodes 20a. 20b and 24 are in ohmic contact with the substrate 30 and the gate electrodes 18a, 18b are in Schottky contact with the substrate 30.

The resistive material of the resistive interconnects 22a, 22b will significantly increase the value of the resistance between the gate electrodes 18a. 18b and the drain electrode 24. Examples of a resistive material are of tantalum nitride or nichrome Since the conductive field plates 16a, 16b are positioned on top of insulating layers 38a, 38b, no DC current will flow into the conductive field plates 16a, 16b. Therefore the resistor provided by the resistive material of the resistive interconnects 22a, 22b will have no effect on its intended function of reducing the time average electric fields between the drain and gate electrodes. However, the resistances of the resistive interconnects 26a, 28b effectively rf decouples the gates 18a, 18b and the field plates 16a, 16b, respectively. The effective resistance of the resistive interconnects 18a, 18b must be high enough such that significant input power is not absorbed by the resistive interconnects 18a, 18b since this would result in gain reduction. The effect of increased resistance R of the resistive interconnects 18a, 18b is seen from the following analysis: The effective admittance at the left end of the structure 10 is

$${y}_{eff} = \frac{R}{[ {R}^{2} + \frac{1}{( {ω}^{2} \cdot {C}_{fp}^{2} )} ]} + j \cdot ( ω \cdot {C}_{gs} ) \cdot [ 1 + \frac{1}{( {ω}^{2} \cdot {C}_{fp} \cdot {C}_{gs} \cdot {R}^{2} + \frac{{C}_{gs}}{{C}_{fp}} )} ] \qquad Eq . 2$$

In Equation 2, ω=2πf where f is the operating frequency of the transistors 12a, 12b. It is noted that when R is very small, the admittance is due to C_{gs}+C_{fp}. When R is large such that

$$R ⪢ \frac{1}{ω \sqrt{{C}_{fp} {C}_{gs}}} > \frac{1}{ω {C}_{fp}} \qquad Eq . 3$$

the admittance is due only to C_{gs}. In the last term in Eq. 3, it is assumed that the field plate capacitance is smaller than C_{gs}.

One may calculate the required resistivity of the interconnecting material of the resistive interconnects 18a, 18b from the condition in Eq. 3. Assuming C_{fp}=C_{gs}/4 and that C_{gs}=1.9 pF/mm implies a minimum resistance of 16.6 ohm-mm at 10 GHz. For a 100 micron gate electrode 18a, 18b fingers, the resistance should be several times 166 ohms. For a multifinger 800 micron device, the resistance should be several times 20.2 ohms.

Such resistances should be achievable with standard metals. For example, metal of 6 ohms per square, 100 microns long by 2 microns wide (50 squares) would have a resistance of 300 ohms.

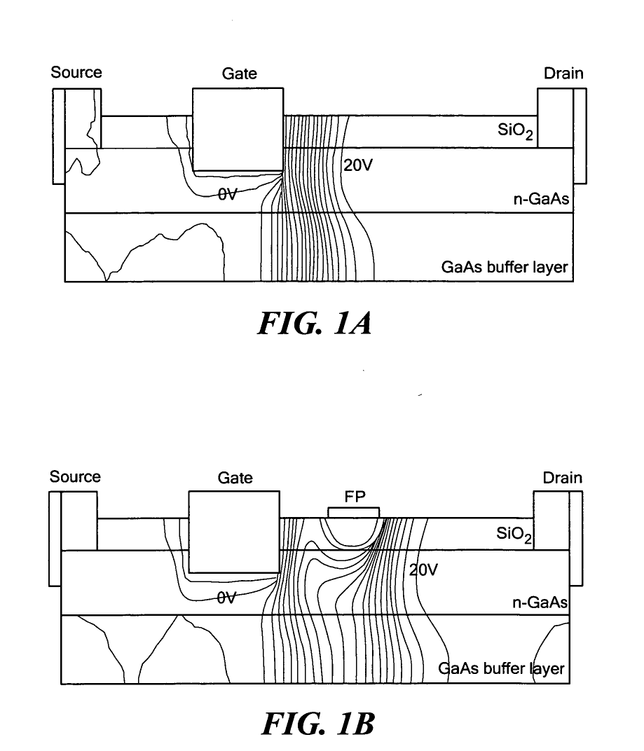

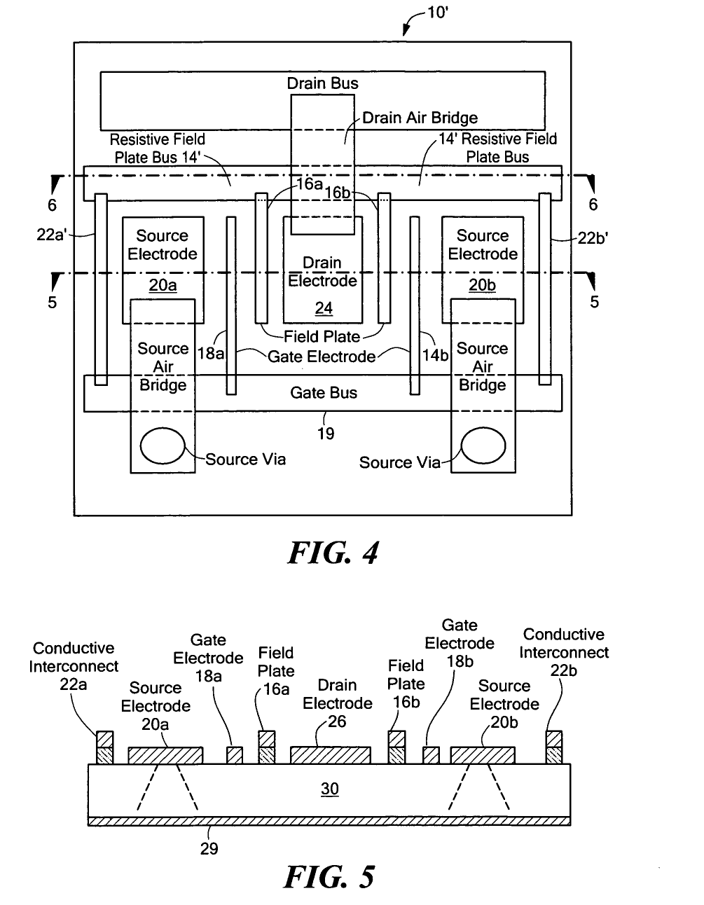

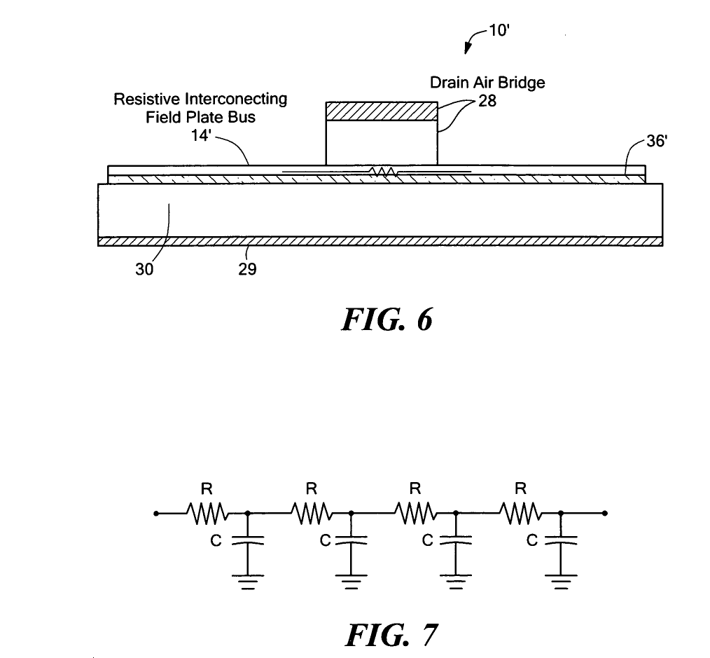

Referring now to FIGS. 4, 5 and 6 an alternative implementation of the decoupled field plate would result from the use of a resistive metal for the conductive field plate bus 14′. In this case, the conductive field plate bus 14 in FIGS. 2 and 3 is replaced with a resistive field plate bus 14′ and the resistive interconnects 22a, 22b of FIGS. 1 and 2 are replaced with conductive interconnects 22a′ and 22b′. The resistive field plate bus 14′ is a distributed network of capacitance and resistance as shown in FIG. 7. This network may be modeled by writing a first order differential equation for the node voltages and loop currents at a point x along the plate 14′. These equations can be combined to give an Eq. 4 for the shunt current as a function of position, x, along the line when it is fed from one end.

$$\frac{{ⅆ}^{2}}{ⅆ {x}^{2}} I = j \cdot ω \cdot {c}_{0} \cdot r \cdot I \qquad Eq . 4$$

Where cₒ is the capacitance per unit length and r is the resistance per unit length along the field plate bus 14′. From Eq. 4, we find

$$I = exp ( - \sqrt{\frac{ω \cdot {c}_{0} \cdot t}{2}} \cdot x ) \cdot exp ( - j \cdot \sqrt{\frac{ω \cdot {c}_{0} \cdot r}{r}} \cdot x ) \qquad Eq . 5$$

This shows that the shunt current decreases exponentially along the length of the field plate bus 14′. Thus, choosing r sufficiently high should result in substantial decoupling of the field plate from the gate electrodes. Care must be taken to insure that rf coupling variation along the length of the gate electrodes 18a, 18b does not result in non-uniform excitation of the gate finger 18a, 18b.

Thus, in FIGS. 2 and 3, for transistor structure 10, the resistive interconnect between the conductive field plates 16a, 16b and the gate electrodes 18a, 18b is provided by resistive elements 18a and 18b and conductive element 14, while in FIGS. 3, 4, and 5, for transistor structure 10′, the resistive interconnect between the conductive field plates 16a, 16b and the gate electrodes 18a, 18b is provided by conductive elements 18a′ and 18b′ and the resistive element 14′.

Referring now to FIG. 1, it is noted that a voltage source may be connected to the field plate bus 14.

A number of embodiments of the invention have been described. Nevertheless, it will be understood that various modifications may be made without departing from the spirit and scope of the invention. Accordingly, other embodiments are within the scope of the following claims.

1. A field effect transistor structure, comprising:
a field effect transistor;
a field plate disposed between a gate electrode of the transistor and a drain electrode of the transistor; and
a resistive interconnect electrically connected between the gate electrode and the field plate.

2. The field effect transistor structure wherein the resistive interconnect comprises a resistive material of the group consisting essentially of tantalum nitride, nichrome or some other highly resistive material.

3. The field effect transistor structure recited in claim 1 wherein the resistive interconnect has a resistivity greater 3 ohms/square.

4. The field effect transistor structure recited in claim 1 wherein the field effect transistor, the field plate, and the resistive interconnect are formed on a substrate, and wherein the resistive interconnect has: a capacitance to the substrate of C_{fp}; and, a resistance R and wherein:
R>1/(2πfC_{fp}) where f is the nominal operating frequency of signals fed to the transistor:

5. A field effect transistor structure, comprising:
a plurality of field effect transistors;
a field plate bus;
a plurality of field plates, each one being disposed between a gate electrode and a drain electrode of a corresponding one of the plurality of transistors, each one of the plurality of field plates being connected to the field plate bus.

6. The field effect transistor structure recited in claim 5 including a voltage source connected to the field plate bus.

7. A field effect transistor structure, comprising:
a plurality of field effect transistors;
a resistive interconnect comprising a field plate bus;
a plurality of field plates, each one being disposed between a gate electrode and a drain electrode of a corresponding one of the plurality of transistors, each one of the plurality of field plates being connected to the resistiv field plate bus;
a plurality of resistive interconnects, each one being electrically connected to the gate electrode and the field plate of a corresponding one of the transistors.

8. A field effect transistor structure, comprising:
a plurality of field effect transistors;
a resistive interconnect comprising a field plate bus;
a plurality of field plates, each one being disposed between a gate electrode and a drain electrode of a corresponding one of the plurality of transistors though the resistive interconnect.

9. The field effect transistor structure recited in claim 8 including a voltage source connected to the field plate bus.

10. A field effect transistor structure, comprising:
a plurality of field effect transistors;
a field plate bus;
a plurality of field plates, each one being disposed between a gate electrode and a drain electrode of a corresponding one of the plurality of transistors, each one of the plurality of field plates being connected to the field plate bus; and
wherein such field plate bus comprises a resistive material electrically connected to the gate electrode and the field plate of a corresponding one of the transistors.

11. The field effect transistor structure recited in claim 10 including a voltage source connected to the field plate bus.

12. A field effect transistor structure, comprising:
a plurality of field effect transistors;
a plurality of field plates, each one being disposed between a gate electrode and a drain electrode of a corresponding one of the plurality of transistors, each one of the plurality of field plates being connected to the field plate bus; and
wherein such field plate bus comprises a resistive material electrically connected to the gate electrode and the field plate of a corresponding one of the transistors.

13. The field effect transistor structure recited in claim 12 including a voltage source connected to the field plate bus.
